(19) United States
(12) Patent Application Publication
(10) Pub. No.: US 2025/0269635 A1
(43) Pub. Date: Aug. 28, 2025

(54) WORKPIECE PROCESSING PREPARATION METHOD AND PROCESSING METHOD

(71) Applicant: DISCO CORPORATION, Tokyo (JP)

(72) Inventors: Kohta NAGATA, Tokyo (JP); Hiroshi ONODERA, Tokyo (JP)

(21) Appl. No.: 19/050,314

(22) Filed: Feb. 11, 2025

(30) Foreign Application Priority Data
Feb. 22, 2024 (JP) 2024-025046

(51) Int. Cl. B32B 37/12; B24B 37/04

(52) U.S. Cl. CPC B32B 37/12; B24B 37/042; B32B 2037/1253; B32B 2457/14

(57) ABSTRACT

A workpiece processing preparation method includes laying first resin on a table, causing a planar member held by a holding pad to face and be pressed against the first resin laid on an upper surface of the table to obtain an integrated body, solidifying with an external stimulus the first resin sandwiched between the planar member and the table, and thereby forming a first resultant, peeling the planar member from the first resultant to form a first resin layer, laying a sheet on an upper surface of the first resin layer after forming the first resin layer, and laying second resin on the sheet.

### BACKGROUND OF THE INVENTION

### Field of the Invention

The present invention relates to a method of processing a plate-shaped workpiece, and particularly, in grinding a workpiece into a flat surface, a method of preparation for forming a reference surface to be used in the grinding by coating one side of the workpiece with resin and for grinding the workpiece to thin the workpiece to a predetermined thickness. Additionally, the present invention relates to a method of processing the prepared workpiece.

### Description of the Related Art

There has been a problem that, in thinning of a wafer as a plate-shaped workpiece, rigidity of the wafer is significantly impaired due to the thinning, and thereby a crack, a warp, or the like occurs at the time of delivery and processing. As disclosed in Japanese Patent Laid-open No. 2004-207606, for example, in order to prevent this problem, there is known a grinding method of grinding a wafer after bonding the wafer on a rigid support substrate.

Moreover, concerning such a grinding method, there is known a method of grinding a wafer to obtain a predetermined thickness after fixing the wafer to a front surface of a support member via liquid resin as a fixing agent, as disclosed in Japanese Patent Laid-open No. 2011-119578, for example.

### SUMMARY OF THE INVENTION

When processing as disclosed in Japanese Patent Laid-open No. 2011-119578 is carried out, it is necessary that the thickness of a bonded resultant including the wafer, the fixing agent, and the support member should have little variation, that is, high flatness should be achieved. Low flatness (large variation in thickness) can cause a crack or chipping at the time of grinding. Further, limitations on thinning depend on the flatness, in other words, low flatness can hinder the thinning to a desired thickness.

In an apparatus configuration as disclosed in Japanese Patent Laid-open No. 2011-119578, for example, accuracy obtained after bonding (variation in thickness of resin) significantly depends on parallelism which is attributable to component accuracy and mounting errors of constituent members of the apparatus. More specifically, the parallelism between a stage (upper base) that holds the wafer as a workpiece under suction and another stage (base plate) on which the support member and the liquid resin are laid can be enhanced through adjustment, but desired accuracy might not be able to be achieved depending on component tolerance and mounting errors. The variation in thickness of the bonded resin decides limitations on the thinning at the time of grinding the composite wafer. Thus, there is a possibility that the wafer cannot be ground to a desired thickness, and even if the wafer is ground to the desired thickness, there arises a problem that variation in thickness of the wafer is large and quality obtained as a result of processing is poor.

Moreover, the adjustment of the parallelism mentioned above is an indispensable step not only for thinning the workpiece but also for forming, in grinding the workpiece flat, a reference surface for use in the grinding by coating one side of the wafer with resin. This adjustment requires a lot of man-hours, and there has been a demand for improvement in this step.

Accordingly, it is an object of the present invention to provide a workpiece processing preparation method of preparing a workpiece to be processed in a state in which the workpiece is held on a table via resin, and a workpiece processing method of processing the workpiece prepared by the processing preparation method.

In accordance with an aspect of the present invention, there is provided a workpiece processing preparation method including laying first resin on a table; causing a planar member held by a holding pad to face and be pressed against the first resin laid on an upper surface of the table to obtain an integrated body, solidifying with an external stimulus the first resin sandwiched between the planar member and the table, and thereby forming a first resultant, peeling the planar member from the first resultant to form a first resin layer, laying a sheet on an upper surface of the first resin layer after forming the first resin layer, laying second resin on the sheet, causing a plate-shaped workpiece held by the holding pad to face and be pressed against the second resin laid on an upper surface of the sheet, to obtain an integrated body, solidifying with an external stimulus the second resin sandwiched between the sheet and the workpiece, and thereby forming a second resultant, and removing the first resin layer from the second resultant to form a third resultant.

In accordance with another aspect of the present invention, there is provided a workpiece processing preparation method including laying first resin on a table, causing a planar member held by a holding pad to face and be pressed against the first resin laid on an upper surface of the table to obtain an integrated body, solidifying with an external stimulus the first resin sandwiched between the planar member and the table, and thereby forming a first resultant, peeling the planar member from the first resultant to form a first resin layer, laying a sheet on an upper surface of the first resin layer after forming the first resin layer, laying a plate-shaped object on an upper surface of the sheet after laying the sheet, laying second resin on the plate-shaped object, causing a plate-shaped workpiece held by the holding pad to face and be pressed against the second resin laid on an upper surface of the plate-shaped object, to obtain an integrated body, solidifying with an external stimulus the second resin sandwiched between the plate-shaped object and the workpiece, and thereby forming a second resultant, and removing the first resin layer and the sheet from the second resultant to form a third resultant.

Preferably, the planar member has a lower surface with an area larger than an area of a lower surface of the workpiece. Preferably, the planar member has a lower surface with an area larger than an area of a lower surface of the plate-shaped object and an area of a lower surface of the workpiece, and the plate-shaped object has the upper surface with an area larger than the area of the lower surface of the workpiece. Preferably, the first resin and the second resin are each liquid resin that is cured by an external stimulus.

In accordance with a further aspect of the present invention, there is provided, concerning the third resultant prepared by the workpiece processing preparation method, a processing method including causing a holding surface of a chuck table in a grinding apparatus to hold the sheet of the third resultant and causing a grinding unit of the grinding apparatus to grind an upper surface of the workpiece to thin the workpiece to a desired thickness.

In accordance with a still further aspect of the present invention, there is provided, concerning the third resultant prepared by the workpiece processing preparation method, a processing method including causing a holding surface of a chuck table in a grinding apparatus to hold the plate-shaped object of the third resultant and causing a grinding unit of the grinding apparatus to grind an upper surface of the workpiece to thin the workpiece to a desired thickness.

The above and other objects, features and advantages of the present invention and the manner of realizing them will become more apparent, and the invention itself will best be understood from a study of the following description and appended claims with reference to the attached drawings showing some preferred embodiments of the invention.

### BRIEF DESCRIPTION OF THE DRAWINGS

FIG. 1 is a front view illustrating an outline of a configuration of a sticking apparatus;

FIG. 2A is a cross-sectional view illustrating a first resin supplying step;

FIG. 2B is a cross-sectional view illustrating a first resultant forming step;

FIG. 3A is a cross-sectional view illustrating a resin layer forming step;

FIG. 3B is a plan view illustrating a state in which a first resin layer has been formed;

FIG. 4A is a cross-sectional view illustrating a sheet laying step;

FIG. 4B is a plan view illustrating a state in which a sheet has been laid on the first resin layer;

FIG. 5A is a cross-sectional view illustrating a second resin supplying step;

FIG. 5B is a cross-sectional view illustrating a second resultant forming step;

FIG. 6A is a cross-sectional view illustrating a third resultant forming step;

FIG. 6B is a cross-sectional view illustrating a third resultant;

FIG. 7A is a cross-sectional view illustrating a holding step;

FIG. 7B is a cross-sectional view illustrating a grinding step;

FIG. 8A is a cross-sectional view illustrating a state in which no variation is generated in thickness, according to a first embodiment of the present invention;

FIG. 8B is a cross-sectional view illustrating a state in which variation is generated in thickness, according to a comparative example unlike the present invention;

FIG. 9 is a cross-sectional view illustrating a plate-shaped object laying step according to a second embodiment of the present invention;

FIG. 10A is a cross-sectional view illustrating a second resin supplying step according to the second embodiment;

FIG. 10B is a cross-sectional view illustrating a second resultant forming step according to the second embodiment;

FIG. 11A is a cross-sectional view illustrating a third resultant forming step according to the second embodiment; and

FIG. 11B is a cross-sectional view illustrating the third resultant forming step according to the second embodiment.

### DETAILED DESCRIPTION OF THE PREFERRED EMBODIMENTS

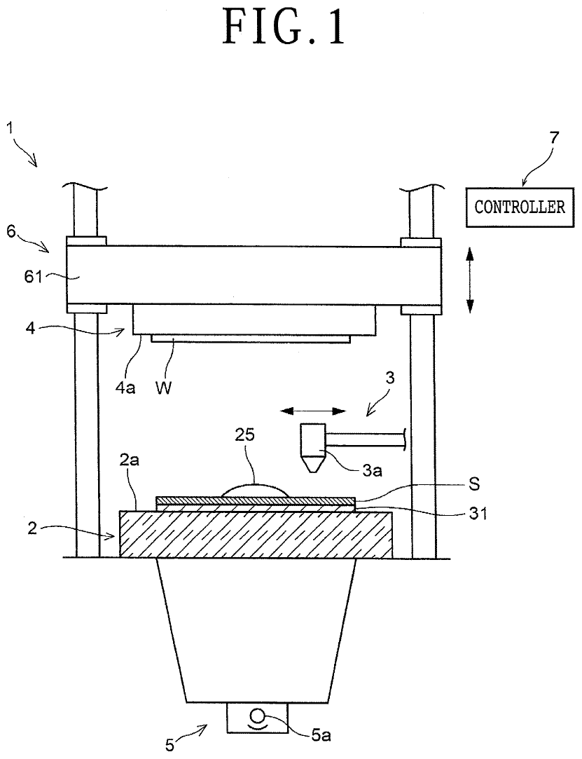

Description will hereinafter be made of embodiments of the present invention with reference to the accompanying drawings. FIG. 1 is a view illustrating an outline of a configuration of a sticking apparatus used in preparation for processing of a workpiece. FIG. 1 illustrates a state in which a wafer W as a workpiece is made to face resin 25 laid on an upper surface of a sheet S in the sticking apparatus, denoted by 1.

The sticking apparatus 1 includes a table 2, a holding pad 4, an elevating mechanism 6, an ultraviolet irradiation unit 5, a resin supply unit 3, and a controller 7 for controlling various operating sections.

The table 2 is configured to have a horizontal upper surface 2a and transmit ultraviolet rays, and, for example, is made of a transparent member such as glass. A suction groove leading to a suction source not illustrated is formed in the horizontal upper surface 2a, and the upper surface 2a acts as a suction-holding surface when negative pressure is generated on the upper surface 2a.

The holding pad 4 is disposed above the horizontal upper surface 2a of the table 2, and a suction groove leading to a suction source not illustrated is formed in a horizontal lower surface 4a of the holding pad 4. The lower surface 4a acts as a suction-holding surface when negative pressure is generated on the lower surface 4a. One side (upper surface) of the wafer W as the workpiece is held under suction by the lower surface 4a, and another surface (lower surface) of the wafer W is exposed.

The holding pad 4 is fixed to a lower surface side of an elevating base 61 of the elevating mechanism 6 and moves up and down together with the elevating base 61. The elevating mechanism 6 has an actuator not illustrated and moves the elevating base 61 up and down by causing the actuator to operate.

The ultraviolet irradiation unit 5 is disposed below the table 2 and has a light source 5a for emitting ultraviolet light. As will be described later in detail, ultraviolet rays pass through the table 2 and the sheet S and solidify the resin 25.

The resin supply unit 3 has a supply nozzle 3a for supplying liquid resin 25 onto the upper surface of the sheet S or the like laid on the table 2. The supply nozzle 3a is movable by an actuator not illustrated, between a supply position at which the supply nozzle 3a is located above a central position of the table 2 and a retracted position at which the supply nozzle 3a is located away from the table 2. The supply nozzle 3a is connected to a resin supply source not illustrated and can supply a predetermined amount of the resin 25 onto the upper surface of the sheet S or the like. Described next is a processing preparation method using the sticking apparatus configured as described above.

### FIRST EMBODIMENT

### First Resin Supplying Step

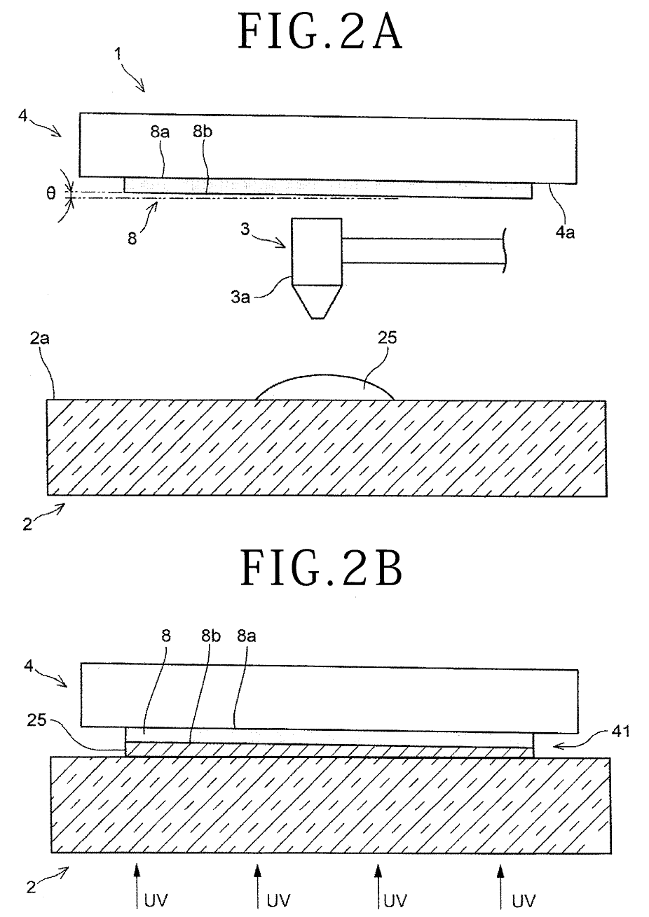

This is a step of laying the resin 25 on the table 2 as illustrated in FIG. 2A. More specifically, the supply nozzle 3a is positioned above a substantially central position of the horizontal upper surface 2a of the table 2, the resin 25 is dropped from the supply nozzle 3a, and thereby the predetermined amount of resin 25 is supplied onto the upper surface 2a. The resin 25 is, for example, ultraviolet curing resin, and “ResiLoc” (registered trademark) manufactured by DISCO Corporation is used as the resin 25. The resin 25 transmits ultraviolet rays after it is solidified.

### First Resultant Forming Step

This is a step of causing a planar member 8 held by the holding pad 4 to face and be pressed against the resin 25 laid on the upper surface 2a of the table 2, to obtain an integrated body, solidifying with an external stimulus the resin 25 sandwiched between the planar member 8 and the table 2, and thereby forming a first resultant (first laminate) 41, as illustrated in FIG. 2A and FIG. 2B.

More specifically, first, the supply nozzle 3a is retracted away from the position below the holding pad 4. Then, the lower surface 4a of the holding pad 4 holds an upper surface 8a of the planar member 8 under suction, and the elevating mechanism 6 (FIG. 1) moves the planar member 8 downward. When a lower surface 8b of the planar member 8 reaches the resin 25, the resin 25 is spread all over between the planar member 8 and the table 2.

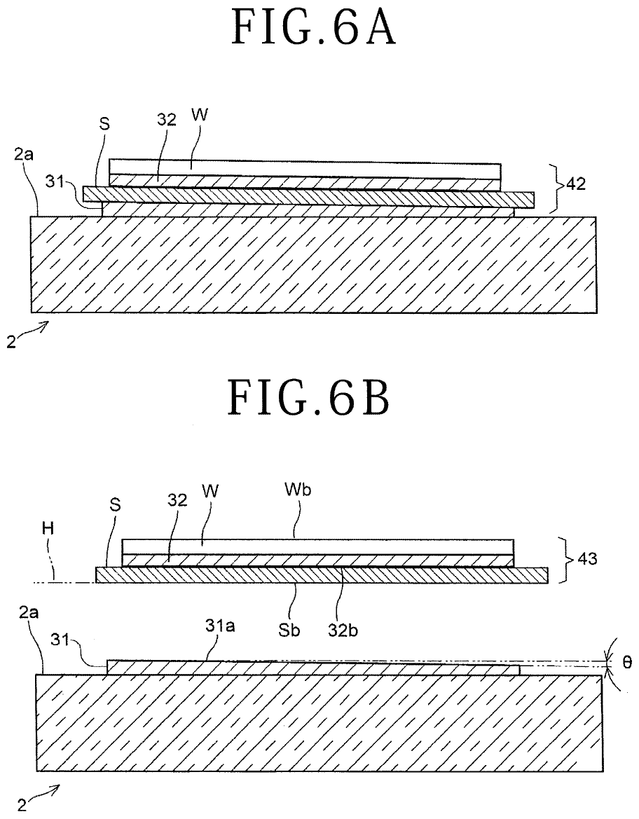

The lower surface 8b of the planar member 8 used here has an area larger than an area of a lower surface (front surface Wa) of the wafer W to be described later. In a case in which the wafer W to be described later has a diameter of 12 inches, for example, a silicon wafer having a diameter of 306 mm, which is larger than the wafer W, is used. As a result, an area of a first resin layer 31 to be described later can be made larger than the area of the wafer Was illustrated in FIG. 6A, so that the wafer W can be supported by the first resin layer 31. In addition, total thickness variation (TTV) of the planar member 8 is preferably equal to or smaller than 3 μm, more preferably, equal to or smaller than 1 μm. The planar member 8 may be a silicon wafer, or may alternatively be a plate made of glass, for example. Further, the planar member 8 may be circular in shape, or may alternatively be rectangular in shape.

Then, as illustrated in FIG. 2B, the planar member 8 is moved downward to a predetermined height with respect to the table 2 such that the planar member 8 is pressed against the resin 25. In this state, the ultraviolet irradiation unit 5 (FIG. 1) irradiates the resin 25 with ultraviolet rays UV from below through the table 2, thereby solidifying the resin 25. Consequently, the resin 25 having a predetermined thickness is solidified.

As described above, in the present embodiment, it is irradiation with ultraviolet rays that apply an external stimulus for solidifying the resin 25. It is to be noted that heat may alternatively be used as an external stimulus, for example. In this case, thermosetting resin may be used as resin.

### Resin Layer Forming Step

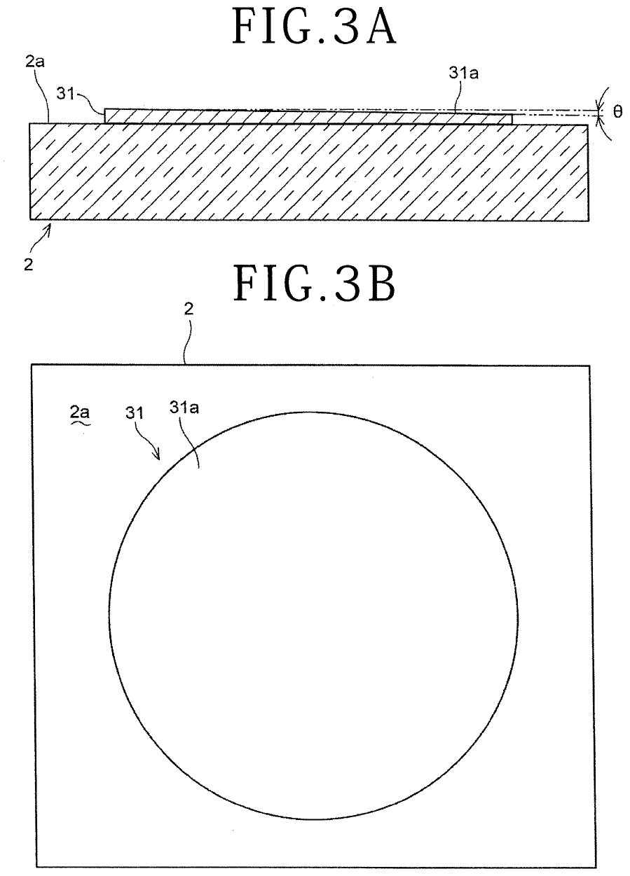

This is a step of peeling the planar member 8 from the first resultant 41 illustrated in FIG. 2B to form the first resin layer 31 as illustrated in FIG. 3A.

As illustrated in FIG. 3A, the first resin layer 31 is left unremoved on the upper surface 2a of the table 2, and an inclination of the planar member 8 (FIG. 2A) has been transferred to an upper surface 31a of the first resin layer 31. In the example of FIG. 3A, the upper surface 31a of the first resin layer 31 has such an inclination of an angle θ that the upper surface 31a is lower in height at a right part thereof than at a left part thereof, and the angle θ is equal to the angle of the inclination of the planar member 8 (holding pad 4) as illustrated in FIG. 2A. It is to be noted that, in FIG. 2A, the inclination of the planar member 8 is regarded also as an inclination of the holding pad 4, and the planar member 8 held by the holding pad 4 is held in a posture inclined by the angle e.

FIG. 3B is a plan view of FIG. 3A, illustrating a state in which the first resin layer 31 has been formed on the table 2 with the planar member 8 (FIG. 2A) peeled off. The first resin layer 31 transmits ultraviolet rays.

It is to be noted that the peeling between the first resin layer 31 and the planar member 8 (FIG. 2A) can be carried out easily since the resin 25 has been solidified by ultraviolet rays and formed into the first resin layer 31 and adhesive strength acting in a direction against the peeling is weak.

### Sheet Laying Step

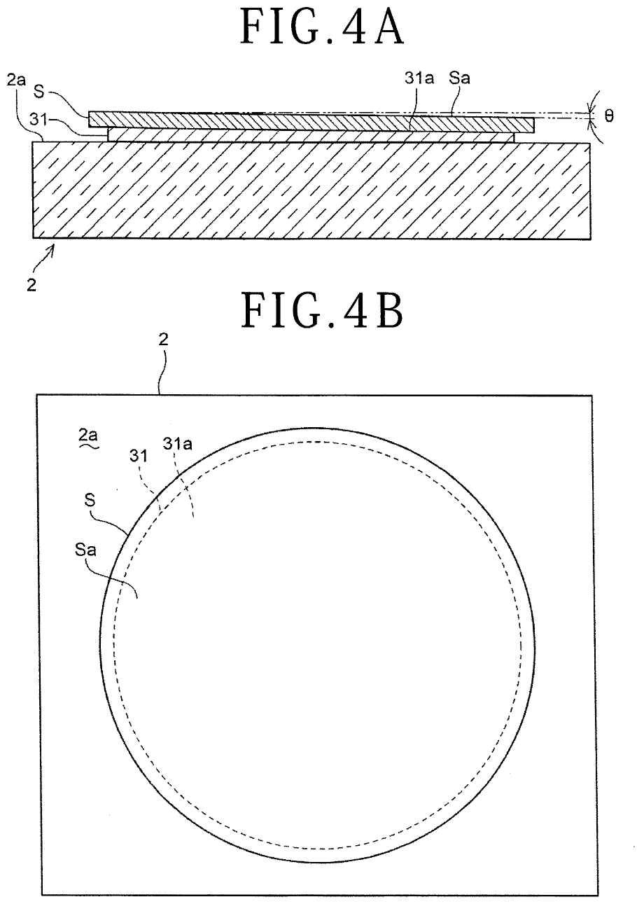

This is a step of laying the sheet S on the upper surface 31a of the first resin layer 31 as illustrated in FIG. 4A, after the resin layer forming step is carried out. The sheet S is, for example, formed by a film made of a transparent polyethylene terephthalate (PET) material that transmits ultraviolet rays.

FIG. 4B is a plan view of FIG. 4A, illustrating a state in which the sheet S has been laid on the first resin layer 31. The sheet S is larger in diameter than the first resin layer 31, but this is not limitative. Further, the sheet S may be circular in shape, or may alternatively be rectangular in shape.

As illustrated in FIG. 4A, the sheet S is laid on the upper surface 31a of the first resin layer 31 that is inclined by the angle θ, and thus, an upper surface Sa of the sheet S is also inclined by the angle θ.

### Second Resin Supplying Step

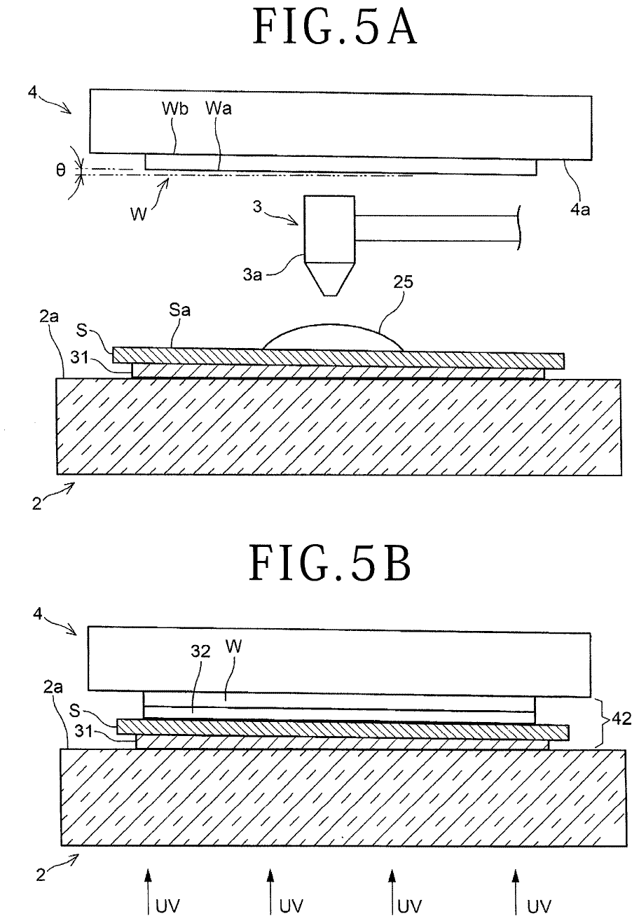

This is a step of laying the resin 25 on the sheet S as illustrated in FIG. 5A.

More specifically, the supply nozzle 3a is positioned above the sheet S, the resin 25 is dropped from the supply nozzle 3a onto the upper surface Sa of the sheet S, and thereby a predetermined amount of the resin 25 is supplied onto the upper surface Sa of the sheet S. The resin 25 in this step may be or may not be the same as the resin used in the first resultant forming step described above.

### Second Resultant Forming Step

This is a step of causing the plate-shaped wafer W as the workpiece held by the holding pad 4 to face and be pressed against the resin 25 laid on the upper surface Sa of the sheet S, to obtain an integrated body, solidifying with an external stimulus the resin 25 sandwiched between the sheet S and the wafer W, and thereby forming a second resultant (second laminate) 42, as illustrated in FIG. 5A and FIG. 5B.

More specifically, first, the supply nozzle 3a is retracted away from the position below the holding pad 4. Then, the lower surface 4a of the holding pad 4 holds the upper surface (back surface Wb) of the wafer W under suction, and the elevating mechanism 6 (FIG. 1) moves the wafer W downward. When the wafer W reaches the resin 25, the resin 25 is spread all over between the wafer W and the sheet S.

The wafer W is, for example, a silicon wafer and is to be thinned later by being ground on a back surface Wb thereof. It is to be noted that an oxide wafer, a compound wafer, a device wafer, a mold wafer, or the like may be used as the workpiece besides a silicon wafer. The upper surface of the wafer W, that is, the surface held by the holding pad 4, is not bent at the time of the pressing of the resin 25 since it is held by the holding pad 4.

In the state in which the resin 25 is being pressed by the wafer W, as illustrated in FIG. 5B, the ultraviolet irradiation unit 5 (FIG. 1) irradiates the resin 25 with ultraviolet rays UV from below through the table 2, the first resin layer 31, and the sheet S, thereby solidifying the resin 25.

As described above, in the present embodiment, it is irradiation with ultraviolet rays that apply an external stimulus for solidifying the resin 25. It is to be noted that heat may alternatively be used as an external stimulus, for example. In this case, thermosetting resin may be used as resin.

In this manner, a second resin layer 32 is formed between the wafer W and the sheet S. The second resin layer 32 transmits ultraviolet rays.

### Third Resultant Forming Step

This is a step of releasing the holding of the wafer W by the holding pad 4 and removing the first resin layer 31 from the second resultant 42 to form a third resultant (third laminate) 43 as illustrated in FIG. 6A and FIG. 6B. In other words, this is a step of peeing the sheet S from the first resin layer 31 to form the third resultant 43. The third resultant 43 includes the sheet S, the second resin layer 32, and the wafer W.

The peeling between the first resin layer 31 and the sheet S can be carried out easily since the resin 25 has been solidified by ultraviolet rays and formed into the first resin layer 31 and adhesive strength acting in a direction against the peeling is weak.

As described above, the sheet S and an upper surface of the second resin layer 32 are inclined by the angle θ, and also, the wafer W is held by the holding pad 4 in a posture inclined by the angle θ. Hence, a lower surface Sb of the sheet S lies in parallel with the exposed surface of the wafer W, that is, the back surface Wb of the wafer W. Accordingly, when the lower surface Sb of the sheet S is set in parallel with a horizontal surface H as illustrated in FIG. 6B, the back surface Wb of the wafer W is also horizontal, so that the wafer W can be thinned to a uniform thickness in later thinning processing.

The method of forming the third resultant 43 in this manner is regarded as the processing preparation method of preparing the wafer W as the workpiece. The third resultant 43 thus prepared is to be processed in the following manner.

It is to be noted that, in the state in which the third resultant forming step has been completed, the first resin layer 31 is left unremoved on the upper surface 2a of the table 2 as illustrated in FIG. 6B, and this is a state same as the state in which the resin layer forming step has been completed as illustrated in FIG. 3A. Therefore, when a bonded resultant equivalent to the third resultant 43 is to be formed for another wafer W or another workpiece, the resin layer forming step can be omitted. In other words, the first resin layer 31 can be reused as a “reference surface,” and it is possible to successively make use of the “reference surface” without carrying out the resin layer forming step for forming a “reference surface” for each workpiece. Accordingly, throughout is enhanced.

### Holding Step

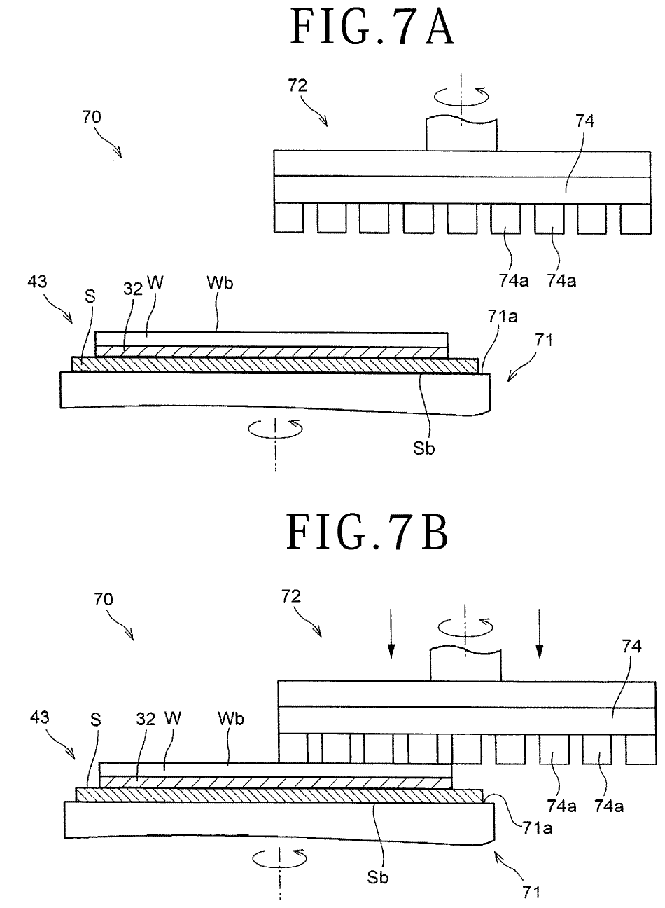

This is a step of causing a holding surface 71a of a chuck table 71 in a grinding apparatus 70 to hold the lower surface Sb of the sheet S of the third resultant 43 as illustrated in FIG. 7A. When the lower surface Sb of the sheet S is held on the chuck table 71, the back surface Wb of the wafer W as the workpiece is exposed.

The grinding apparatus 70 mainly includes the chuck table 71 and a grinding unit 72, and grinds the back surface Wb of the wafer W as the workpiece to thin the wafer W. A suction groove not illustrated is formed in the holding surface 71a of the chuck table 71, and the third resultant 43 is held under suction on the holding surface 71a when negative pressure is generated in the suction groove. The chuck table 71 is rotatable about its central axis by a rotational mechanism not illustrated.

The grinding unit 72 has a grinding wheel 74 on which a plurality of grindstones 74a are annularly arranged at intervals. The grinding wheel 74 is rotated about its central axis at a predetermined speed by a rotational mechanism not illustrated and is grinding-fed at a predetermined speed by a grinding-feed mechanism not illustrated.

### Grinding Step

This is a step of causing the grinding unit 72, which is a grinding unit in the grinding apparatus 70, to grind the back surface Wb as the upper surface of the wafer W to thin the wafer W to a desired thickness as illustrated in FIG. 7B.

More specifically, the chuck table 71 is rotated about its central axis to rotate the third resultant 43, and at the same time, the grinding wheel 74 is grinding-fed downward while being rotated, so that the back surface Wb of the wafer W is ground, and the wafer W is thinned to a predetermined thickness. Since the wafer W is fixed to the second resin layer 32 having rigidity, grinding can be carried out while occurrence of a crack, a warp, or the like is suppressed.

It is to be noted that, between the second resin layer 32 and the sheet S and between the second resin layer 32 and the wafer W, liquid resin enters gaps and is then solidified, and this contributes to mechanical adhesion (anchor effect) between the second resin layer 32 and the sheet S and between the second resin layer 32 and the wafer W. Hence, the grinding can be carried out in a stable condition without occurrence of displacement between layers included in the third resultant 43.

According to the embodiment described above, for example, even in a case in which the lower surface 4a of the holding pad 4 that is a part of constituent members of the sticking apparatus 1 is inclined and is not parallel to the horizontal upper surface 2a of the table 2 as illustrated in FIG. 2A, that is, in a case in which high parallelism cannot be secured due to component tolerance and mounting errors, the lower surface Sb of the sheet S, a lower surface 32b of the second resin layer 32, and the processing target surface (back surface Wb) of the wafer W as the workpiece can be made parallel to one another in the third resultant 43 illustrated in FIG. 6B.

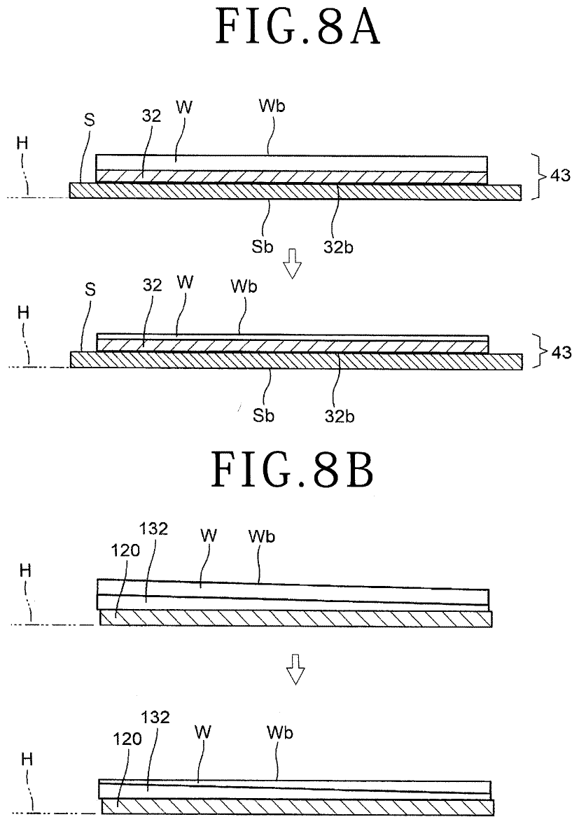

Therefore, in the grinding, the wafer W is thinned uniformly as illustrated in FIG. 8A, and a thinned wafer W with no thickness variation can be obtained. Eliminating thickness variation enhances the quality of chips to be manufactured eventually.

In contrast, FIG. 8B illustrates a comparative example unlike the present embodiment, in which a wafer W as a workpiece is integrated with a second plate-shaped object 120 via a resin layer 132. Since a back surface Wb of the wafer W is inclined, the wafer W is not thinned uniformly at the time of grinding, thereby generating thickness variation. There is a concern that such thickness variation causes lowering in quality of chips to be manufactured eventually.

### SECOND EMBODIMENT

The “first resin supplying step,” the “first resultant forming step,” the “resin layer forming step,” and the “sheet laying step” described in the first embodiment with reference to FIG. 2A through FIG. 4B are included also in the second embodiment, but redundant description is omitted. In the second embodiment, a “plate-shaped object laying step,” a “second resin supplying step,” a “second resultant forming step,” and a “third resultant forming step” are subsequently carried out.

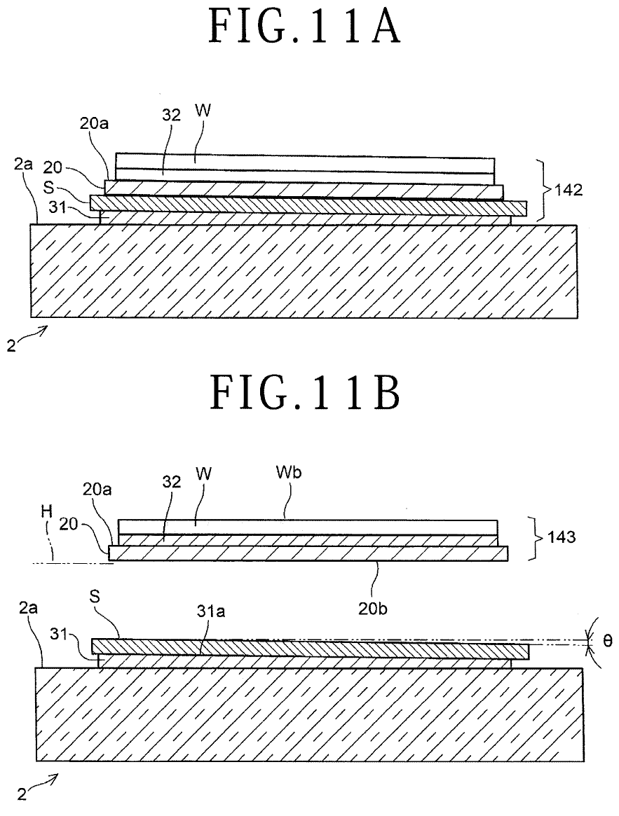

It is to be noted that the planar member 8 used in the second embodiment has the lower surface 8b (FIG. 2A) with an area larger than an area of a lower surface 20b of a plate-shaped object 20 and the area of the lower surface (front surface Wa) of the workpiece (wafer W). For example, in a case in which the wafer W to be described later has a diameter of 12 inches, a silicon wafer having a diameter of 306 mm, which is larger than the wafer W, is used. As a result, the area of the upper surface of the first resin layer 31 can be made larger than the area of the lower surface 20b of the plate-shaped object 20 and the area of the lower surface of the wafer Was illustrated in FIG. 11A, so that the plate-shaped object 20 and the wafer W can be supported by the first resin layer 31. Moreover, the plate-shaped object 20 has an upper surface 20a with an area larger than the area of the lower surface of the wafer W, so that the wafer W can be supported by the plate-shaped object 20.

### Plate-Shaped Object Laying Step

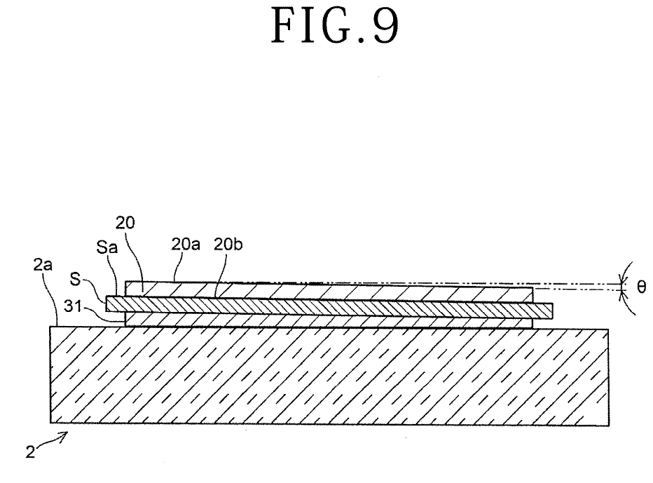

This is a step of laying the plate-shaped object 20 on the upper surface Sa of the sheet S as illustrated in FIG. 9, after the sheet laying step is carried out.

Here, the plate-shaped object 20 is, for example, formed by a plate made of a transparent glass material that transmits ultraviolet rays, and is high in rigidity. The plate-shaped object 20 is used to function as a support member for the wafer W to be thinned later, by being bonded and integrated with the wafer W, and to thereby prevent a crack and a warp of the wafer W. Further, preferably, the plate-shaped object 20 is satisfactorily low in TTV.

The plate-shaped object 20 is laid on the upper surface Sa of the sheet S that is inclined by the angle o, and thus, the upper surface 20a of the plate-shaped object 20 is also inclined by the angle θ.

### Second Resin Supplying Step

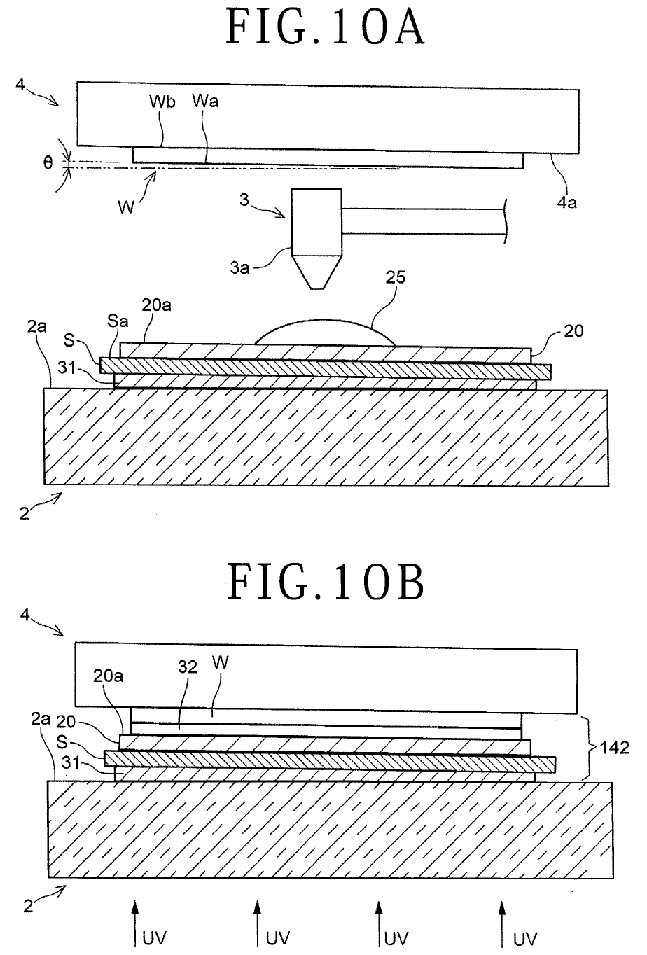

This is a step of laying the resin 25 on the plate-shaped object 20 as illustrated in FIG. 10A. More specifically, the supply nozzle 3a is positioned above the plate-shaped object 20, the resin 25 is dropped from the supply nozzle 3a onto the upper surface 20a of the plate-shaped object 20, and thereby a predetermined amount of the resin 25 is supplied to the upper surface 20a of the plate-shaped object 20. The resin 25 in this step may be or may not be the same as the resin used in the first resultant forming step described above.

### Second Resultant Forming Step

This is a step of causing the plate-shaped wafer W as the workpiece held by the holding pad 4 to face and be pressed against the resin 25 laid on the upper surface 20a of the plate-shaped object 20, to obtain an integrated body, solidifying with an external stimulus the resin 25 sandwiched between the plate-shaped object 20 and the wafer W, and thereby forming a second resultant (second laminate) 142, as illustrated in FIG. 10A and FIG. 10B.

More specifically, first, the supply nozzle 3a is retracted away from the position below the holding pad 4. Then, the lower surface 4a of the holding pad 4 holds the back surface Wb of the wafer W under suction, and the elevating mechanism 6 (FIG. 1) moves the wafer W downward. When the wafer W reaches the resin 25, the resin 25 is spread all over between the wafer W and the plate-shaped object 20.

Then, as illustrated in FIG. 10B, in the state in which the resin 25 is being pressed by the wafer W, the ultraviolet irradiation unit 5 (FIG. 1) irradiates the resin 25 with ultraviolet rays UV from below through the table 2, the first resin layer 31, the sheet S, and the plate-shaped object 20, thereby solidifying the resin 25.

As described above, in the present embodiment, it is irradiation with ultraviolet rays that apply an external stimulus for solidifying the resin 25. It is to be noted that heat may alternatively be used as an external stimulus, for example. In this case, thermosetting resin may be used as resin.

In this manner, a second resin layer 32 is formed between the wafer W and the plate-shaped object 20. The second resin layer 32 transmits ultraviolet rays.

### Third Resultant Forming Step

This is a step of releasing the holding of the wafer W by the holding pad 4 and removing the first resin layer 31 and the sheet S from the second resultant 142 to form a third resultant (third laminate) 143 as illustrated in FIG. 11A and FIG. 11B. In other words, this is a step of peeing the plate-shaped object 20 from the sheet S to form the third resultant 143. The third resultant 143 includes the plate-shaped object 20, the second resin layer 32, and the wafer W.

The plate-shaped object 20 can easily be peeled from the sheet S since no substance contributing to adhesion between the plate-shaped object 20 and the sheet S is present.

Further, as described above, the upper surface 20a of the plate-shaped object 20 is inclined by the angle θ, and also, the wafer W is held by the holding pad 4 in a posture inclined by the angle θ. Hence, the lower surface 20b of the plate-shaped object 20 lies in parallel with the exposed surface of the wafer W, that is, the back surface Wb of the wafer W. Accordingly, when the lower surface 20b of the plate-shaped object 20 is set in parallel with the horizontal surface H as illustrated in FIG. 11B, the back surface Wb of the wafer W is also horizontal, so that the wafer W can be thinned to a uniform thickness in later thinning processing.

As in the first embodiment, the holding step and the grinding step are carried out for the third resultant 143, thereby thinning the wafer W.

According to the present invention, as described in the first and second embodiment, even in a case in which high parallelism cannot be secured due to component tolerance and mounting errors in constituent members of an apparatus for forming a resin layer, a third resultant (third laminate) that has extremely small variation in thickness and is thus flat with high accuracy can be prepared. Further, in the third resultant, a workpiece is fixed by resin, and accordingly, it is possible to prepare a state suitable for thinning the workpiece exposed on an upper surface of the resultant.

In addition, according to the present invention, the first resin layer can be reused as a “reference surface,” and it is possible to successively make use of the “reference surface” without carrying out the resin layer forming step for forming a “reference surface” for each workpiece. Accordingly, throughout is enhanced.

The present invention is not limited to the details of the above described preferred embodiment. The scope of the invention is defined by the appended claims and all changes and modifications as fall within the equivalence of the scope of the claims are therefore to be embraced by the invention.

What is claimed is:

1. A workpiece processing preparation method comprising:
laying first resin on a table;
causing a planar member held by a holding pad to face and be pressed against the first resin laid on an upper surface of the table to obtain an integrated body, solidifying with an external stimulus the first resin sandwiched between the planar member and the table, and thereby forming a first resultant;
peeling the planar member from the first resultant to form a first resin layer;
laying a sheet on an upper surface of the first resin layer after forming the first resin layer;
laying second resin on the sheet;
causing a plate-shaped workpiece held by the holding pad to face and be pressed against the second resin laid on an upper surface of the sheet, to obtain an integrated body, solidifying with an external stimulus the second resin sandwiched between the sheet and the workpiece, and thereby forming a second resultant; and
removing the first resin layer from the second resultant to form a third resultant.

2. The workpiece processing preparation method according to claim 1, wherein the planar member has a lower surface with an area larger than an area of a lower surface of the workpiece.

3. The workpiece processing preparation method according to claim 1, wherein the first resin and the second resin are each liquid resin that is cured by an external stimulus.

4. The workpiece processing preparation method according to claim 2, wherein the first resin and the second resin are each liquid resin that is cured by an external stimulus.

5. A workpiece processing preparation method comprising:
laying first resin on a table;
causing a planar member held by a holding pad to face and be pressed against the first resin laid on an upper surface of the table to obtain an integrated body, solidifying with an external stimulus the first resin sandwiched between the planar member and the table, and thereby forming a first resultant;
peeling the planar member from the first resultant to form a first resin layer;
laying a sheet on an upper surface of the first resin layer after forming the first resin layer;
laying a plate-shaped object on an upper surface of the sheet after laying the sheet;
laying second resin on the plate-shaped object;
causing a plate-shaped workpiece held by the holding pad to face and be pressed against the second resin laid on an upper surface of the plate-shaped object, to obtain an integrated body, solidifying with an external stimulus the second resin sandwiched between the plate-shaped object and the workpiece, and thereby forming a second resultant; and
removing the first resin layer and the sheet from the second resultant to form a third resultant.

6. The workpiece processing preparation method according to claim 5, wherein
the planar member has a lower surface with an area larger than an area of a lower surface of the plate-shaped object and an area of a lower surface of the workpiece, and
the plate-shaped object has the upper surface with an area larger than the area of the lower surface of the workpiece.

7. The workpiece processing preparation method according to claim 5, wherein the first resin and the second resin are each liquid resin that is cured by an external stimulus.

8. The workpiece processing preparation method according to claim 6, wherein the first resin and the second resin are each liquid resin that is cured by an external stimulus.

9. A processing method comprising:
laying first resin on a table;
causing a planar member held by a holding pad to face and be pressed against the first resin laid on an upper surface of the table to obtain an integrated body, solidifying with an external stimulus the first resin sandwiched between the planar member and the table, and thereby forming a first resultant;
peeling the planar member from the first resultant to form a first resin layer;
laying a sheet on an upper surface of the first resin layer after forming the first resin layer;
laying second resin on the sheet;
causing a plate-shaped workpiece held by the holding pad to face and be pressed against the second resin laid on an upper surface of the sheet, to obtain an integrated body, solidifying with an external stimulus the second resin sandwiched between the sheet and the workpiece, and thereby forming a second resultant;
removing the first resin layer from the second resultant to form a third resultant;
causing a holding surface of a chuck table in a grinding apparatus to hold the sheet of the third resultant; and
causing a grinding unit of the grinding apparatus to grind an upper surface of the workpiece to thin the workpiece to a desired thickness.

10. The processing method according to claim 9, wherein the first resin and the second resin are each liquid resin that is cured by an external stimulus.

11. A processing method comprising:
laying first resin on a table;
causing a planar member held by a holding pad to face and be pressed against the first resin laid on an upper surface of the table to obtain an integrated body, solidifying with an external stimulus the first resin sandwiched between the planar member and the table, and thereby forming a first resultant;
peeling the planar member from the first resultant to form a first resin layer;
laying a sheet on an upper surface of the first resin layer after forming the first resin layer;
laying a plate-shaped object on an upper surface of the sheet after laying the sheet;
laying second resin on the plate-shaped object;
causing a plate-shaped workpiece held by the holding pad to face and be pressed against the second resin laid on an upper surface of the plate-shaped object, to obtain an integrated body, solidifying with an external stimulus the second resin sandwiched between the plate-shaped object and the workpiece, and thereby forming a second resultant;
removing the first resin layer and the sheet from the second resultant to form a third resultant;
causing a holding surface of a chuck table in a grinding apparatus to hold the plate-shaped object of the third resultant; and
causing a grinding unit of the grinding apparatus to grind an upper surface of the workpiece to thin the workpiece to a desired thickness.

12. The processing method according to claim 11, wherein the first resin and the second resin are each liquid resin that is cured by an external stimulus.
